(19) United States
(12) Patent Application Publication
(10) Pub. No.: US 2016/0163953 A1
(43) Pub. Date: Jun. 9, 2016

(54) PIEZOELECTRIC ACTUATOR DRIVING CIRCUIT, DRIVING SIGNAL GENERATING CIRCUIT, AND DEVICE AND METHOD OF DRIVING PIEZOELECTRIC ACTUATOR USING THE SAME

(71) Applicant: Samsung Electro-Mechanics Co., Ltd., Suwon-Si (KR)

(72) Inventor: Chan Woo Park, Suwon-Si (KR)

(73) Assignee: Samsung Electro-Mechanics Co., Ltd., Suwon-Si (KR)

(21) Appl. No.: 14/229,776

(22) Filed: Mar. 28, 2014

(30) Foreign Application Priority Data
Dec. 30, 2013 (KR) 10-2013-0166897

(51) Int. Cl. H01L 41/04

(52) U.S. Cl. CPC H01L 41/042

(57) ABSTRACT

A piezoelectric actuator driving device may include: a control unit receiving waveform information including information on an output waveform to output digital values for generating the output waveform; a sampling clock generation unit using the output waveform to generate a variable sampling clock; and a digital-to-analog conversion unit outputting analog values corresponding to the digital values based on the variable sampling clock.

### CROSS-REFERENCE TO RELATED APPLICATION

This application claims the benefit of Korean Patent Application No. 10-2013-0166897 filed on Dec. 30, 2013, with the Korean Intellectual Property Office, the disclosure of which is incorporated herein by reference.

### BACKGROUND

The present disclosure relates to a piezoelectric actuator driving circuit and a driving signal generating circuit, and a device and a method of driving a piezoelectric actuator using the same.

As interest for user interface increases and related technology is developed, technology related to response to a user input within terminal environment has become an essential component of user interface.

At its early stage, the response technology was used to provide a user with simple vibrations to intuitively confirm that the user input has been received.

Recently, as providing a precise response or vibration for a user input has become an essential component, it has become crucial to provide more precise vibration. Therefore, in order to resolve the issue, touch response technology is migrating from the conventional motor-driven technology to haptic technology which can provide various response elements.

The haptic technology refers to an entire system that provides tactile feedback to a user and may provide tactile feedback to the user by vibrating a vibration element to deliver physical force. At an early stage, the haptic technology merely provided simple confirmation for a user input. However, recently, there has been a demand to provide various types of responses for emotional feedback based on more precise control.

To this end, it is required to provide three-dimensional vibration patterns using various frequency bands, and in order to satisfy such demands, a piezoelectric actuator formed of a ceramic material has been recently employed. Such a piezoelectric actuator has advantages over an existing linear resonant actuator formed of magnetic or a vibration motor in that it has a faster response speed, less noise, and a higher resonant bandwidth. Accordingly, minute and three-dimensional vibrations can be variously expressed.

Since such a piezoelectric actuator uses a sinusoidal wave as its driving signal, it is essential to generate a precise sinusoidal wave with no distortion for more precise control. In other words, because a piezoelectric element is driven with a sinusoidal wave, it is necessary to obtain wave accuracy of a sinusoidal wave generated from a piezoelectric actuator driving device in order to accurately drive the piezoelectric element.

According to previous technology for driving a piezoelectric actuator, however, it is difficult to generate a precise sinusoidal wave. According to the previous technology for driving a piezoelectric actuator, the number of digital values sampled during digital-to-analog conversion is changed depending on the frequency of an output sinusoidal wave. Accordingly, if the frequency of an output sinusoidal wave is variable, the sinusoidal wave may not be accurately generated or may be generated with distortion.

### SUMMARY

An exemplary embodiment in the present disclosure may provide a piezoelectric actuator driving circuit and a driving signal generating circuit capable of more precisely generating a sinusoidal wave using all of digital values in a look-up table even if the frequency of an output waveform is changed in such a manner that digital-to-analog conversion is performed with a changed sampling clock using the frequency of the output waveform, and a device and a method of driving a piezoelectric actuator using the same.

According to an exemplary embodiment in the present disclosure, a piezoelectric actuator driving device may include: a control unit receiving waveform information including information on an output waveform to output digital values for generating the output waveform; a sampling clock generation unit using the output waveform to generate a variable sampling clock; and a digital-to-analog conversion unit outputting analog values corresponding to the digital values based on the variable sampling clock.

According to an exemplary embodiment in the present disclosure, a piezoelectric actuator driving device may include: a control unit outputting digital values for generating an output waveform based on a variable sampling clock generated using a frequency of the output waveform; and a digital-to-analog conversion unit outputting analog values corresponding to the digital values output from the control unit.

According to an exemplary embodiment in the present disclosure, a piezoelectric actuator driving circuit may include: a sampling clock generation circuit checking a frequency of an output waveform and generating a variable sampling clock considering the frequency of the output waveform; and a control circuit outputting digital values referring to a predetermined look-up table based on the variable sampling clock.

According to an exemplary embodiment in the present disclosure, a driving signal generating circuit may include: a sampling clock generation circuit checking a frequency of an output waveform and generating a variable sampling clock considering the frequency of the output waveform; and a digital-to-analog conversion circuit sequentially receiving a plurality of digital values and sequentially outputting analog values corresponding to the plurality of digital values based on the variable sampling clock.

According to an exemplary embodiment in the present disclosure, a method of driving a piezoelectric actuator may include: checking a frequency of an output waveform and generating a variable sampling clock considering the frequency of the output waveform; outputting at least some of a plurality of digital values included in a predetermined look-up table; and outputting analog values corresponding to the at least some of the digital values based on the variable sampling clock.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a piezoelectric actuator driving device according to an exemplary embodiment of the present disclosure;

FIG. 2 shows examples of signals output from elements in the piezoelectric actuator driving device illustrated in FIG. 1;

FIGS. 3A and 3B are views illustrating examples of sinusoidal waves output from the piezoelectric actuator driving device illustrated in FIG. 1;

FIG. 4 is a block diagram illustrating a piezoelectric actuator driving device according to an exemplary embodiment of the present disclosure;

FIG. 5 is a block diagram illustrating an example of the sampling clock generation unit illustrated in FIG. 4;

FIG. 6 is a block diagram illustrating an example of the control unit illustrated in FIG. 4;

FIG. 7 is a block diagram illustrating an example of the digital-to-analog conversion unit illustrated in FIG. 4;

FIG. 8 is a block diagram illustrating a piezoelectric actuator driving circuit according to an exemplary embodiment of the present disclosure;

FIG. 9 is a block diagram illustrating a driving signal generating circuit according to an exemplary embodiment of the present disclosure;

FIG. 10 is a flow chart illustrating a method of driving a piezoelectric actuator according to an exemplary embodiment of the present disclosure;

FIG. 11 is a flow chart illustrating an example of operation S1010 of the method illustrated in FIG. 10; and

FIG. 12 is a flow chart illustrating an example of operation S1020 of the method illustrated in FIG. 10.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

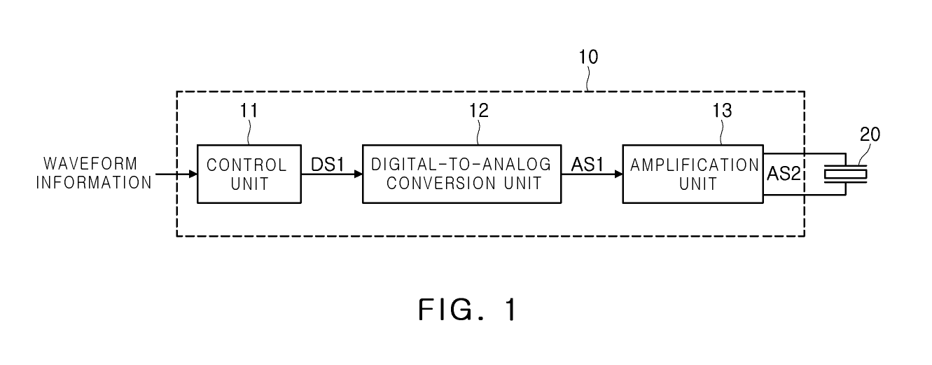

FIG. 1 is a block diagram illustrating a piezoelectric actuator driving device 10 according to an exemplary embodiment of the present disclosure.

Referring to FIG. 1, a control unit 11 may externally receive waveform information and output digital values DS1 for generating an output waveform by referring to a predetermined look-up table. A digital-to-analog conversion unit 12 may output an analog signal AS1 corresponding to the digital values DS1. An amplification unit 13 may receive the analog signal AS1 and provide it to a piezoelectric element 20.

Here, the digital-to-analog conversion unit 12 may use a predetermined sampling clock such as a system clock.

The look-up table may include a plurality of digital values for generating a predetermined reference waveform at a predetermined sampling clock.

In the following descriptions, the operation of the piezoelectric actuator driving device 10 will be described in detail with reference to an example in which the reference sampling clock and the reference waveform of the look-up table are 8 KHz and 7.8125 Hz, respectively, the sampling clock of the digital-to-analog conversion unit 12 is 8 KHz, and the output waveform from the piezoelectric actuator driving device 10 is 7.8125 Hz.

Since the reference sampling clock and the reference waveform of the look-up table are 8 KHz and 7.8125 Hz, respectively, the look-up table may have 1,024 digital values.

Since the output waveform of the piezoelectric actuator driving device 10 is 7.8125 Hz, which is equal to the reference waveform of the look-up table, the control unit 11 may sequentially output 1,024 digital values DS1 included in the look-up table every 8 KHz. The digital-to-analog conversion unit 12 may convert the digital values DS1 input from the control unit 11 at the sampling clock, i.e., at every 8 KHz, into an analog signal AS1. The amplification unit 13 may differentially amplify the analog signal AS1 to output it.

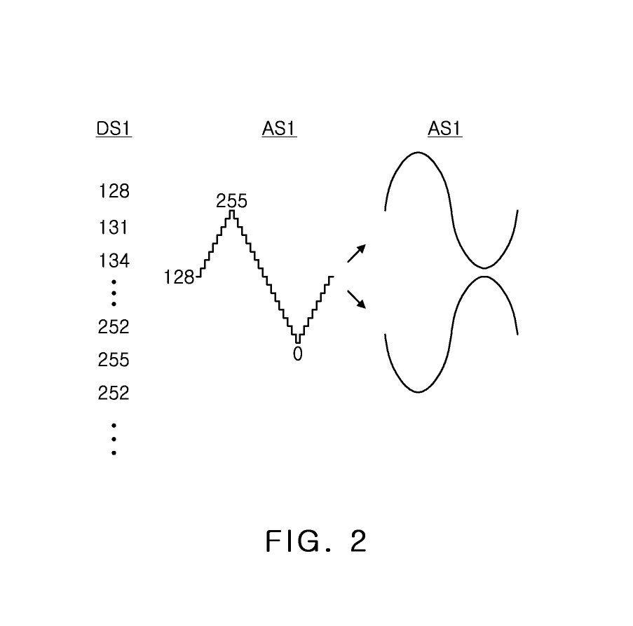

The signals output from the elements of the piezoelectric actuator driving device according to the exemplary embodiment are illustrated in FIG. 2.

Referring to FIG. 2, the control unit 11 may refer to the look-up table to output digital values DS1 included in the look-up table at every 8 KHz. The digital-to-analog conversion unit 12 may convert them into an analog signal AS1 to output it. Since the digital-to-analog conversion unit 12 converts the digital values into the analog signal, a sinusoidal wave having a step function form is output, as illustrated in FIG. 2. The amplification unit 13 may be a differential amplifier, and may filter the received analog signal AS1 and generate two sinusoidal wave forms in anti-phase AS2 to provide them to both input terminals of the piezoelectric element 20.

In the above example, since the reference waveform of the look-up table and the output waveform of the piezoelectric actuator driving device 10 are 7.8125 Hz, all of the data values in the look-up table are used to generate a sinusoidal wave, and thus, no distortion occurs in the output waveform.

Unlike the above example, however, if the reference waveform of the look-up table and the output waveform of the piezoelectric actuator driving device 10 are different from each other, a distortion may occur in the output waveform.

In the following description, the operation of the piezoelectric actuator driving device 10 will be described in detail with reference to an example in which the reference sampling clock and the reference waveform of the look-up table are 8 KHz and 7.8125 Hz, respectively, the sampling clock of the digital-to-analog conversion unit 12 is 8 KHz, and the output waveform from the piezoelectric actuator driving device 10 is 15.625 Hz.

In this example, the frequency of the output waveform from the piezoelectric actuator driving device 10 is 15.625 Hz, which is twice the frequency of the reference waveform of the look-up table, 7.8125 Hz. Accordingly, not all of digital values in the look-up table are used.

That is, in order to output digital values DS1 in the look-up table at every 8 KHz to generate an output waveform of 15.625 Hz, the control unit 11 only uses 512 data values out of the 1,024 data values in the look-up table. That is, the control unit 11 may sequentially output only odd-numbered digital values (or only even-numbered digital values) stored in the look-up table at every 8 KHz, generating one period of the output waveform of 15.625 Hz.

This is because it is not possible to use all of the digital values in the look-up table during sampling when the output waveform from the piezoelectric actuator driving device has a higher frequency than that of the reference waveform of the look-up table, 7.8125 Hz.

Therefore, when the frequency of the output waveform from the piezoelectric actuator driving device 10 is higher than that of the reference waveform of the look-up table, only some of the digital values in the look-up table are used to generate a sinusoidal wave. For this reason, in practice, as the frequency of the output waveform becomes larger, the form of the output sinusoidal wave becomes more inaccurate, and a distortion may occur.

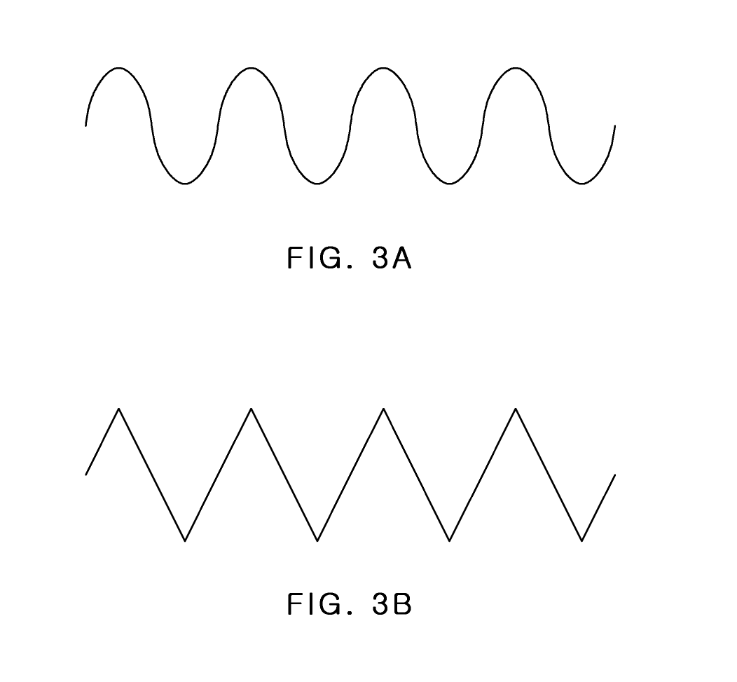

FIGS. 3A and 3B are diagrams illustrating distortions in an output waveform due to high frequency. FIG. 3A is a graph illustrating a waveform in a case in which the reference waveform of the look-up table is 7.8125 Hz and the output waveform from the piezoelectric actuator driving device 10 is 7.8125 Hz, and FIG. 3B is a graph illustrating a waveform in a case in which the reference waveform of the look-up table is 7.8125 Hz and the output waveform from the piezoelectric actuator driving device 10 is 1.992 KHz. In addition, the sampling clock is 8 KHz in FIGS. 3A and 3B.

In FIG. 3A, the output waveform from the piezoelectric actuator driving device is the same as the reference waveform of the look-up table, such that a normal sinusoidal wave is output.

On the other hand, in FIG. 3B, only four data values out of 1,024 data values in the look-up table are used to generate one period of the output waveform. Here, the frequency of the output waveform from the piezoelectric actuator driving device 10 is 1.992 KHz, while the frequency of the reference waveform of the look-up table is 7.8125 Hz, such that there is a large difference between frequencies of the two waveforms. Therefore, only four data values in the look-up table, i.e., only four sampling points, are used to generate one period of the output waveform of 1.992 KHz, such that a saw tooth waveform is output as illustrated, instead of a sinusoidal wave. With such a saw tooth waveform, it is difficult to generate an accurate sinusoidal wave even after subjection to filtering. Thus, a distortion may occur in the output waveform from the piezoelectric element 20 and in turn, the driving characteristic may be affected.

As can be seen from FIGS. 3A and 3B, since the sampling clock for digital-to-analog conversion is not changed even if the frequency of the output waveform from the piezoelectric actuator driving device 10 is changed, only some of the digital data values in the look-up table are used to generate the output waveform. Therefore, when the output waveform from the piezoelectric actuator driving device 10 is different from the reference waveform of the look-up table, the sampling density for the output waveform becomes lower and thus, a distortion is more likely to occur in the output sinusoidal waveform.

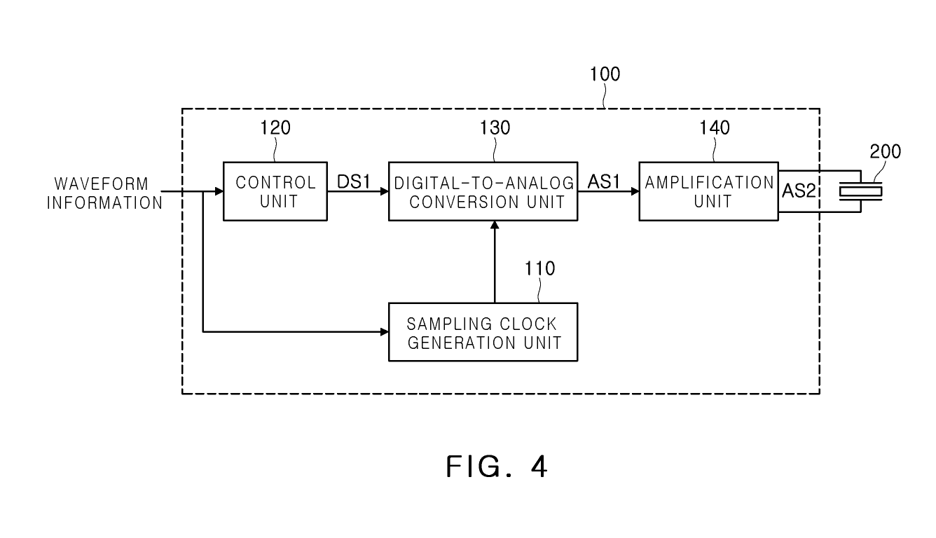

Hereinafter, various exemplary embodiments of the present disclosure for preventing a distortion in a sinusoidal wave will be described with reference to FIGS. 4 through 9.

FIG. 4 is a block diagram illustrating a piezoelectric actuator driving device according to an exemplary embodiment of the present disclosure.

Referring to FIG. 4, the piezoelectric actuator driving device 100 according to the exemplary embodiment may include a sampling clock generating unit 110, a control unit 120, a digital-to-analog conversion unit 130, and an amplification unit 140.

The sampling clock generating unit 110 may receive waveform information and may check the frequency of an output waveform AS2.

In an exemplary embodiment, the sampling clock generation unit 110 may use the frequency ratio between the reference waveform of the look-up table and the output waveform to generate a variable sampling clock. The generated variable sampling clock may be input to the digital-to-analog conversion unit 130.

Here, the waveform information input from an external-MCU, a mobile phone CPU or a main control unit may include information on at least one of the frequency, cycle and amplitude of the output waveform. The frequency of the output waveform may vary, and accordingly, the sampling clock generation unit 110 may generate a variable sampling clock for the variable output waveform.

In an exemplary embodiment, the sampling clock generation unit 110 may generate the variable sampling clock by applying the ratio of the frequency of the reference waveform of the look-up table to the frequency of the output waveform in the reference sampling clock in the look-up table. For example, assuming that the frequency of the reference waveform of the look-up table is 7.8125 Hz and the frequency of the output waveform is 15.625 Hz, the ratio of the frequency of the reference waveform of the look-up table to the frequency of the output waveform is 15.625/7.8125, two. Accordingly, the sampling clock generation unit 110 may multiply the reference sampling clock 8 MHz by two to generate the variable sampling clock, 16 MHz.

In an exemplary embodiment, the waveform information that is input from the outside may be created based on the reference waveform of the look-up table. For example, when the frequency of the reference waveform of the look-up table is 7.8125 Hz and the frequency of the output waveform is 15.625 Hz, the waveform information may be input as two, which is the ratio of the frequency of the output waveform to the frequency of the reference waveform. Accordingly, the sampling clock generation unit 110 may apply information on the frequency of the output waveform in the waveform information, two, in the reference sampling clock, 8 MHz, to determine the frequency of the variable sampling clock, 16 MHz.

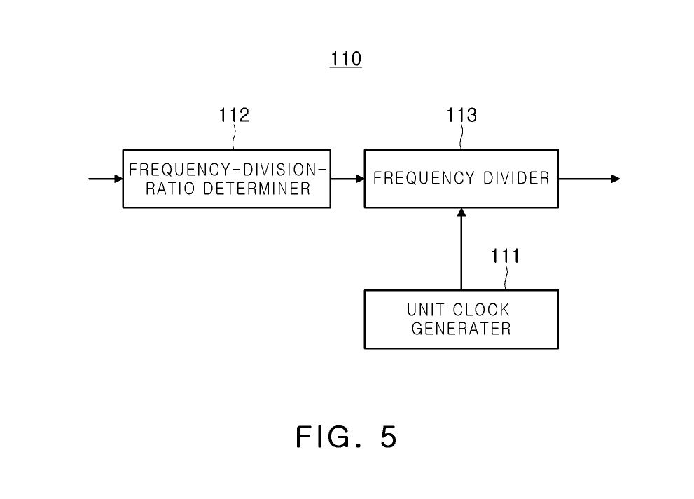

In an exemplary embodiment, the sampling clock generation unit 110 may divide the frequency of a predetermined unit clock to generate the variable sampling clock. The above exemplary embodiment will be described below with reference to FIG. 5.

The control unit 120 may externally receive the waveform information and output digital values DS1 for generating the output waveform.

In an exemplary embodiment, the control unit 120 may refer to the look-up table to output digital values. That is, the control unit 120 may receive waveform information from the outside and refer to the look-up table on a predetermined reference waveform to output digital values DS1 for generating the output waveform.

In another exemplary embodiment, the control unit 120 may use a predetermined function to output digital values. That is, the control unit 120 may receive waveform information from the outside and use the function on a predetermined reference waveform to output digital values DS1 for generating the output waveform.

The look-up table may include a plurality of digital values for generating one period of a sinusoidal wave having a predetermined reference waveform at a predetermined reference sampling clock. For example, when the reference sampling clock and the reference waveform of the look-up table are 8 KHz and 7.8125 Hz, respectively, the look-up table may have 1,024 digital values for generating the sinusoidal wave of 7.8125 Hz.

In an exemplary embodiment of the present disclosure, the control unit 120 may use all of digital values in the look-up table, without considering a difference between frequencies of the reference waveform and the output waveform, to generate one period of the output waveform. That is, the control unit 120 may use all of a plurality of digital values in the look-up table to generate one period of the output waveform, regardless of whether the frequency of the output waveform is changed or not.

In the second example described above with reference to FIG. 1, the sampling clock is fixed so that only some of the data values in the look-up table have to be used by comparing the reference waveform of the look-up table with the output waveform. On the contrary, according to the exemplary embodiment of the present disclosure, the variable sampling clock is provided reflecting the change of the output waveform, such that all of the data values in the look-up table can be used by using the variable sampling clock changed according to the change of the output waveform. Therefore, the control unit 120 may output all of the plurality of digital values included in the look-up table at every one period of the output waveform, regardless of whether the frequency of the output waveform is changed or not.

In an exemplary embodiment, when the variable sampling clock is changed, the control unit 120 may be synchronized with the changed variable sampling clock to output the digital values included in the look-up table. That is, when the frequency of the output waveform is changed, the variable sampling clock may be changed accordingly, such that digital-to-analog conversion may be conducted based on the changed variable sampling clock. Therefore, the control unit 120 may sequentially output all of the digital values in the look-up table in accordance with the changed variable sampling clock.

For example, when the frequency of the reference waveform of the look-up table is 7.8125 Hz and the frequency of the reference sampling clock is 8 MHz, the look-up table has 1,024 digital values. Assuming that the output waveform is 15.625 Hz, the sampling clock generation unit 110 may generate the variable sampling clock of 16 MHz, as described above. Accordingly, the control unit 120 may also output digital values in the look-up table at every 16 MHz. That is, although the data values in the look-up table are determined based on the reference sampling clock, 8 MHz, the control unit 120 may output the digital values based on the variable sampling clock generated in the sampling clock generation unit 110 instead of the reference sampling clock in the look-up table. Accordingly, even if the frequency of the output waveform is changed to 15.626 Hz, the data values in the look-up table are output based on the variable sampling clock, 16 MHz, and the control unit 120 may sequentially output a total of 1,024 data values based on the variable sampling clock, 16 MHz, so as to generate one period of the output waveform having the frequency of 15.625 Hz.

In an exemplary embodiment, the look-up table may further include predetermined reference amplitude information. The waveform information input from the outside may include amplitude information of the output waveform. The control unit 120 may compare the amplitude of the output waveform included in the waveform information with the reference amplitude in the look-up table. If the two amplitudes are different from each other, the control unit 120 may compare the two amplitudes and calculate an amplitude factor, and may reflect the calculated amplitude factor in the digital values in the look-up table to output it. For example, assuming that the reference amplitude of the look-up table is four and the amplitude of the output waveform is six, the control unit 120 may reflect the factor of 1.5 in the digital values in the look-up table to output them. Accordingly, if a data value in the look-up table is five, the control unit 120 may reflect the factor of 1.5 therein to output the digital value of 7.5.

The digital-to-analog conversion unit 130 may output analog values corresponding to the received digital values from the control unit 120 based on the variable sampling clock.

In an exemplary embodiment, since the variable sampling clock may have high frequency, the digital-to-analog conversion unit 130 may operate more stably at high speed. Accordingly, the digital-to-analog conversion unit 130 may be a binary digital-to-analog converter (a binary DAC) satisfying high-speed settling time.

The amplification unit 13 may differentially amplify the analog signal AS1 to output it.

FIG. 5 is a block diagram illustrating an example of the sampling clock generation unit 110 illustrated in FIG. 4.

Referring to FIG. 5, the sampling clock generation unit 110 may include a unit clock generator 111, a frequency-division-ratio determiner 112, and a frequency divider 113.

The unit clock generator 111 may generate a predetermined unit clock. Here, the unit clock may have a frequency higher than that of the reference sampling clock of the look-up table.

The frequency-division-ratio determiner 112 may determine the frequency division ratio of the unit clock for generating the variable sampling clock. For example, assuming that the unit clock is 40 MHz, 5,000 unit clocks may be used to create the variable sampling clock of 8 KHz. Alternatively, 2,500 unit clocks may be used to create the variable sampling clock of 16 KHz. Accordingly, the frequency-division-ratio determiner 112 may compare the variable sampling clock to be created with the unit clock in order to determine the frequency division ratio.

The frequency divider 113 may divide the frequency of the unit clock based on the frequency division ratio provided by the frequency-division-ratio determiner 112 to create the variable sampling clock.

In another exemplary embodiment, the sampling clock generation unit 110 may use a voltage controlled oscillator (VCO) to divide frequencies. That is, the voltage controlled oscillator may store voltage values corresponding to a plurality of frequencies to be divided and may output a data value corresponding to the frequency in the waveform information so as to change the sampling clock.

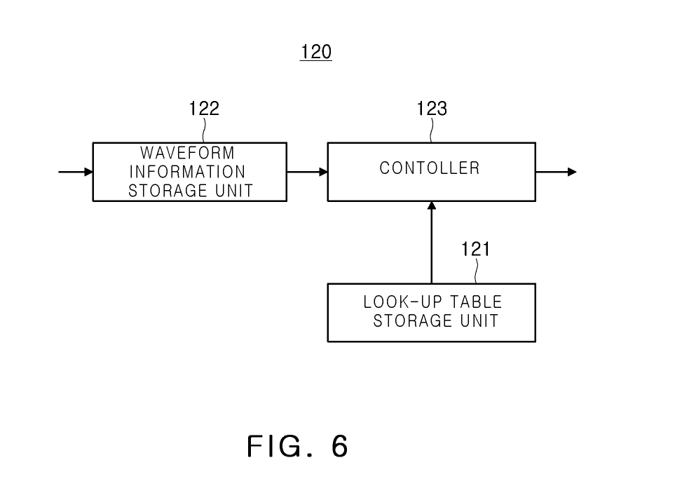

FIG. 6 is a block diagram illustrating an example of the control unit 120 illustrated in FIG. 4.

Referring to FIG. 6, the control unit 120 may include a look-up table storage unit 121, a waveform information storage unit 122, and a controller 123.

The look-up table storage unit 121 may store a look-up table. The look-up table may include a plurality of digital values for generating one period of a sinusoidal wave having a predetermined reference waveform at a predetermined reference sampling clock. In some exemplary embodiments, the look-up table may further include amplitude information of the reference waveform.

The waveform information storage unit 122 may receive the wave information from the outside and store it therein. The received waveform information may include information on at least one of the frequency, cycle and amplitude of the output waveform.

The controller 123 may provide a plurality of digital values included in the look-up table to the digital-to-analog conversion unit 130 based on the variable sampling clock generated in the sampling clock generation unit 110.

In an exemplary embodiment, the controller 123 may check the cycle of the output waveform included in the waveform information so as to output at least some of the plurality of digital values. That is, if the cycle in the waveform information fails to become 1, the output waveform does not form one cycle. Therefore, in this case, the controller 123 may generate the output waveform using only some of the data values in the look-up table, more specifically, at least some of the data values determined sequentially.

In an exemplary embodiment, when the variable sampling clock is changed, the controller 123 may be synchronized with the changed variable sampling clock to output the digital values included in the look-up table.

In an exemplary embodiment, the controller 123 may compare the amplitude of the output waveform included in the waveform information with the reference amplitude of the look-up table. If the two amplitudes are different from each other, the controller 123 may compare the two amplitudes and calculate an amplitude factor, and apply the calculated amplitude factor to the digital values in the look-up table in order to output it.

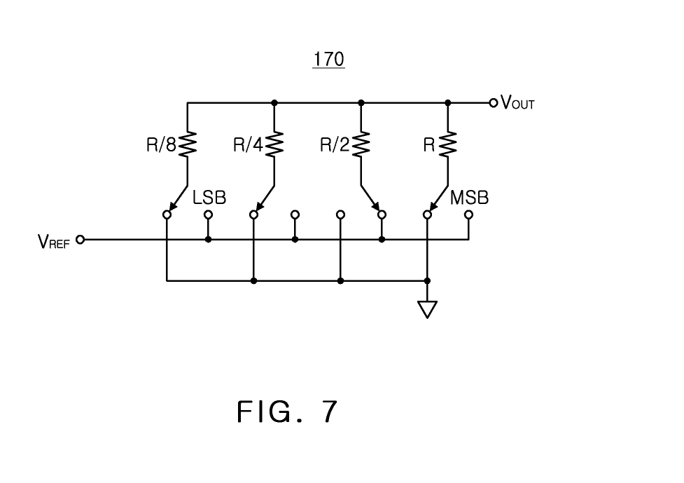

FIG. 7 is a block diagram illustrating an example of the digital-to-analog conversion unit 130 illustrated in FIG. 4.

The digital-to-analog conversion unit 130 may perform switching operations according to an input digital signal. The resistance value is selected by the switching operations, such that the amplitude of an output analog signal is changed. The output from the digital-to-analog conversion unit 130 may be expressed by Mathematical Expression 1 below:

$${V}_{out} = - I {R}_{f} = - {R}_{f} ( \frac{{V}_{1}}{R} + \frac{{V}_{2}}{2 R} + \frac{{V}_{3}}{4 R} + … \frac{{V}_{n}}{{2}^{n - 1} R} ) \qquad [ Mathematical Expression 1 ]$$

Thus far, the piezoelectric actuator driving device according to the exemplary embodiment of the present disclosure has been described with reference to FIGS. 4 through 7.

Hereinafter, a piezoelectric actuator driving circuit and a driving signal generating circuit according to another exemplary embodiment of the present disclosure will be described.

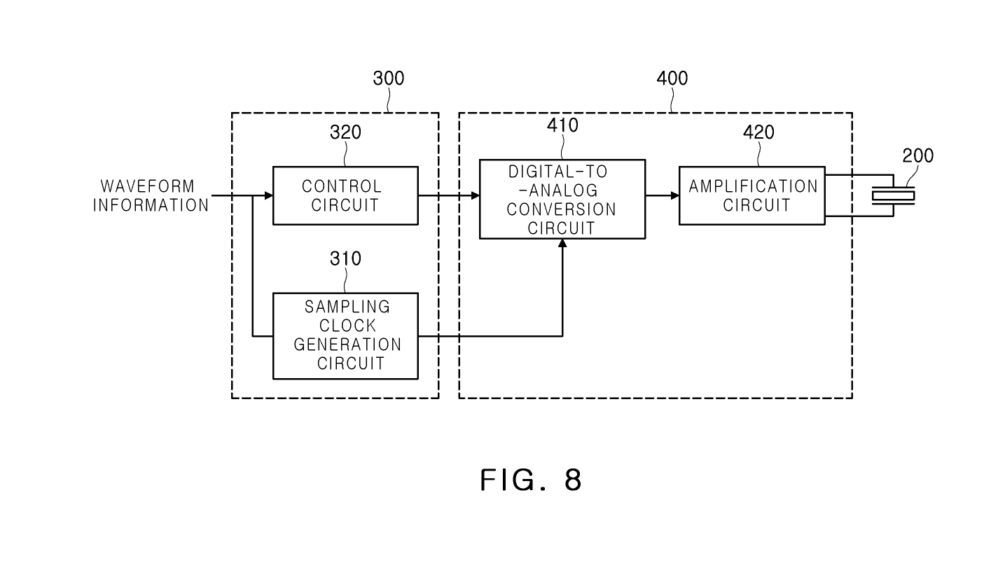

FIG. 8 is a block diagram illustrating a piezoelectric actuator driving circuit according to an exemplary embodiment of the present disclosure.

Referring to FIG. 8, the piezoelectric actuator driving circuit 300 may generate a variable sampling clock based on the frequency of an output waveform to provide it to a driving signal generating circuit 400.

Specifically, the piezoelectric actuator driving circuit 300 may include a sampling clock generation circuit 310 and a control circuit 320.

The sampling clock generation circuit 310 may check the frequency of the output waveform and generate a variable sampling clock in view of the frequency of the output waveform. Here, the sampling clock generation circuit 310 may check the frequency of the output waveform using waveform information input from the outside.

In an exemplary embodiment, the sampling clock generation circuit 310 may determine the variable sampling clock by applying the ratio of the frequency of a reference waveform to the frequency of the output waveform to the reference sampling clock.

In an exemplary embodiment, the sampling clock generation circuit 310 may include a unit clock generator generating a unit clock, a frequency-division-ratio determiner determining the frequency division ratio of the unit clock to the variable sampling clock, and a frequency divider dividing the frequency of the unit clock based on the frequency division ratio to generate the variable sampling clock.

The control circuit 320 may output digital values based on the variable sampling clock by referring to a predetermined look-up table.

Here, the look-up table may include a plurality of digital values for generating a predetermined reference waveform at a predetermined reference sampling clock.

In an exemplary embodiment, the look-up table may further include information on a predetermined reference amplitude, and the control circuit 320 may compare the amplitude of the output waveform included in the waveform information with the reference amplitude to calculate an amplitude factor and apply the amplitude factor to digital values in the look-up table to output them.

The driving signal generating circuit 400 may include a digital-to-analog conversion circuit 410 converting the digital values from the control circuit 320 into analog values based on the variable sampling clock, and an amplification circuit 420 amplifying the output therefrom to provide it to a piezoelectric element 200.

In some exemplary embodiments, the piezoelectric actuator driving circuit 300 may be implemented as a single integrated circuit. For example, the piezoelectric actuator driving circuit 300 may be implemented as an integrated circuit and the driving signal generating circuit 400 may be implemented as an analog circuit.

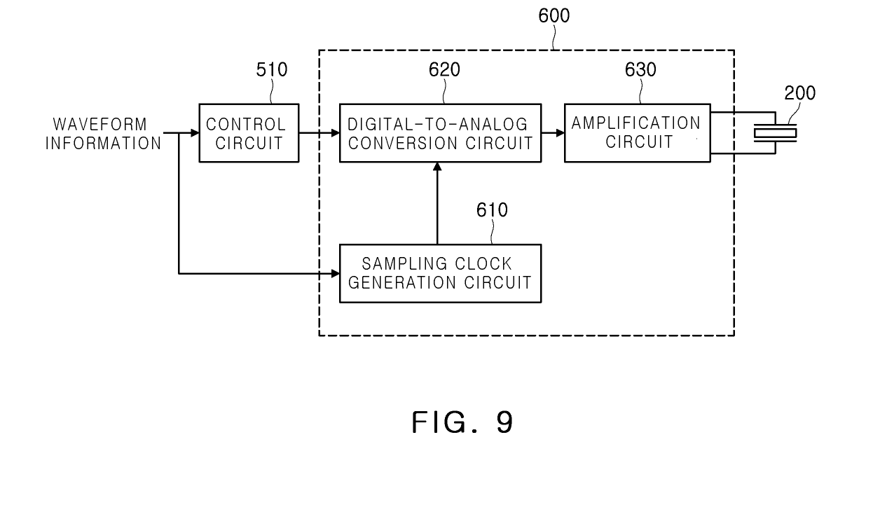

FIG. 9 is a block diagram illustrating a driving signal generating circuit according to an exemplary embodiment of the present disclosure.

Referring to FIG. 9, a control circuit 510 may output digital signals. A driving signal generating circuit 600 may convert the digital signal into an analog signal to output it to a load 200.

Specifically, the driving signal generating circuit 600 may include a sampling clock generating circuit 610 and a digital-to-analog conversion circuit 620. In some exemplary embodiments, the driving signal generating circuit 600 may further include an amplification circuit 630.

The sampling clock generation circuit 610 may check the frequency of the output waveform and generate a variable sampling clock considering the frequency of the output waveform.

In an exemplary embodiment, the sampling clock generation circuit 610 may include a unit clock generator generating a unit clock, a frequency-division-ratio determiner determining the frequency division ratio of the unit clock to the variable sampling clock, and a frequency divider dividing the frequency of the unit clock based on the frequency division ratio in order to generate the variable sampling clock.

The digital-to-analog conversion circuit 620 may sequentially receive a plurality of digital values and sequentially output analog values corresponding to the plurality of digital values based on the variable sampling clock.

In an exemplary embodiment, the digital-to-analog conversion circuit 620 may include a binary digital-to-analog converter.

In the above-described exemplary embodiments, the digital-to-analog conversion unit or the digital-to-analog conversion circuit performed digital-to-analog conversion based on the variable sampling clock. However, the digital-to-analog conversion unit or the digital-to-analog conversion circuit may perform the digital-to-analog conversion upon receiving data from the control unit, instead of performing the digital-to-analog conversion directly based on the variable sampling clock.

In an exemplary embodiment, the control unit may output digital values for generating an output waveform based on the variable sampling clock generated using the frequency of the output waveform. The digital-to-analog conversion unit may output analog values corresponding to the digital values output from the control unit.

That is, according to this exemplary embodiment, the control unit may output the digital values based on the variable sampling clock, and the digital-to-analog conversion unit may perform the digital-to-analog conversion upon receiving the digital values.

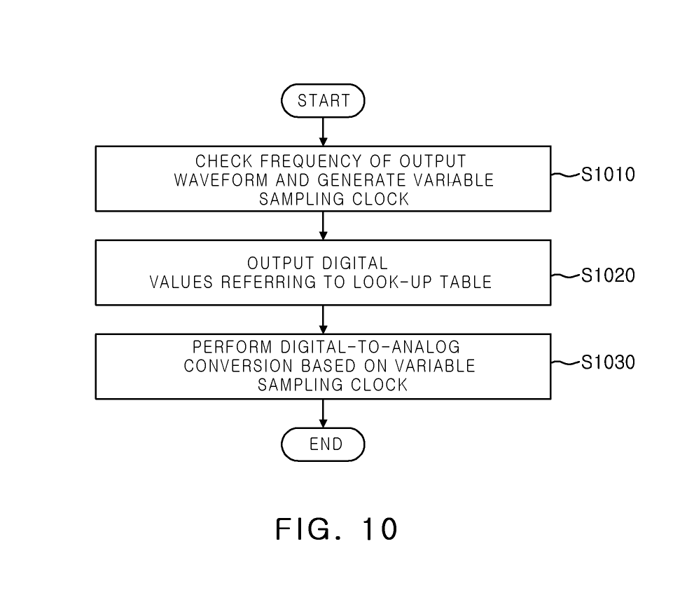

Hereinafter, a method of driving a piezoelectric actuator according to an exemplary embodiment of the present disclosure will be described with reference to FIGS. 10 through 12. Meanwhile, as the method of driving a piezoelectric actuator according to the exemplary embodiment is performed by the piezoelectric actuator driving device described above with reference to FIGS. 4 through 7, redundant descriptions will be omitted.

FIG. 10 is a flow chart illustrating a method of driving a piezoelectric actuator according to the exemplary embodiment.

Referring to FIG. 10, the piezoelectric actuator driving device 100 may check the frequency of an output waveform and may generate a variable sampling clock in view of the frequency of the output waveform (S1010).

In addition, the piezoelectric actuator driving device 100 may output at least some of a plurality of digital values included in a predetermined look-up table (S1020). In an exemplary embodiment, the piezoelectric actuator driving device 100 may output all of the plurality of digital values included in the look-up table at every period of the output waveform.

Then, the piezoelectric actuator driving device 100 may generate analog values corresponding to at least some of the digital values based on the variable sampling clock (S1030).

Although operation S1010 and operation S1020 are performed sequentially in the example illustrated in FIG. 10, operation S1010 and operation S1020 may be performed simultaneously. That is, operation S1020 is not limited to being performed after operation S1010.

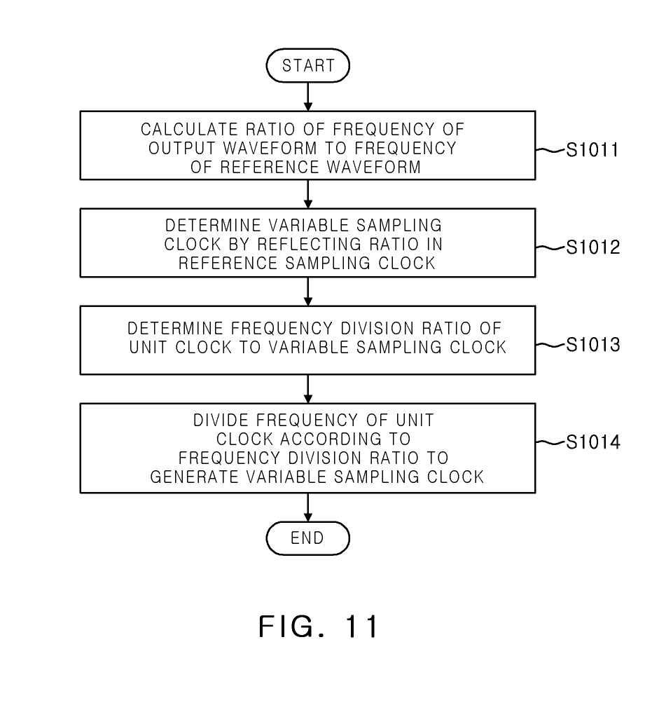

FIG. 11 is a flow chart illustrating an example of operation S1010 of the method illustrated in FIG. 10.

Referring to FIG. 11, the piezoelectric actuator driving device 100 may calculate the ratio of the frequency of the output waveform to the frequency of the reference waveform of the look-up table (S1011).

Then, the piezoelectric actuator driving device 100 may determine the frequency of the variable sampling clock by applying the ratio of the frequency of the output waveform to the frequency of the reference waveform (S1012).

Further, the piezoelectric actuator driving device 100 may determine a frequency division ratio of a predetermined unit clock to the variable sampling clock (S1013) and divide the frequency of the unit clock according to the determined frequency division ratio to generate the variable sampling clock (S1014).

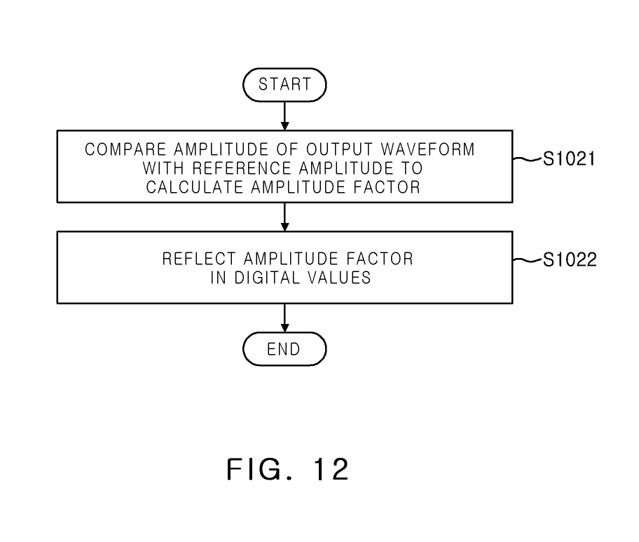

FIG. 12 is a flow chart illustrating an example of operation S1020 of the method illustrated in FIG. 10.

Referring to FIG. 12, the piezoelectric actuator driving device 100 may compare the amplitude of the output waveform with the reference amplitude of the look-up table to calculate an amplitude factor (S1021).

Then, the piezoelectric actuator driving device 100 may apply the amplitude factor to at least some of the digital values to output them.

As set forth above, according to exemplary embodiments of the present disclosure, a sinusoidal wave may be generated more precisely using all of digital values in a look-up table even if the frequency of an output waveform is changed in such a manner that digital-to-analog conversion is performed with a changed sampling clock using the frequency of the output waveform.

While exemplary embodiments have been shown and described above, it will be apparent to those skilled in the art that modifications and variations could be made without departing from the spirit and scope of the present disclosure as defined by the appended claims.

What is claimed is:

1. A piezoelectric actuator driving device, comprising:
a control unit receiving waveform information including information on an output waveform to output digital values for generating the output waveform;
a sampling clock generation unit using the output waveform to generate a variable sampling clock; and
a digital-to-analog conversion unit outputting analog values corresponding to the digital values based on the variable sampling clock.

2. The piezoelectric actuator driving device of claim 1, wherein the control unit uses a look-up table for a predetermined reference waveform to output the digital values.

3. The piezoelectric actuator driving device of claim 2, wherein the sampling clock generation unit generates the variable sampling clock based on a difference between the reference waveform and the output waveform.

4. The piezoelectric actuator driving device of claim 2, wherein the look-up table includes a plurality of digital values for generating the reference waveform at a predetermined reference sampling clock.

5. The piezoelectric actuator driving device of claim 2, wherein the control unit includes:
a waveform information storage unit storing the waveform information;
a look-up table storage unit storing the look-up table; and
a controller providing the plurality of digital values included in the look-up table based on the variable sampling clock to the digital-to-analog conversion unit.

6. The piezoelectric actuator driving device of claim 2, wherein the control unit, if the variable sampling clock is changed, outputs the digital values synchronized with the changed variable sampling clock.

7. The piezoelectric actuator driving device of claim 2, wherein the control unit outputs all of the plurality of digital values included in the look-up table at every period of the output waveform.

8. The piezoelectric actuator driving device of claim 4, wherein the look-up table further includes information on a predetermined reference amplitude, and the control unit compares an amplitude of an output waveform included in the waveform information with the reference amplitude to calculate an amplitude factor and applies the calculated amplitude factor in the digital values to the look-up table to output them.

9. The piezoelectric actuator driving device of claim 4, wherein the sampling clock generation unit calculates a ratio of a frequency of the output waveform to a frequency of the reference waveform and applies the ratio to the reference sampling clock to generate the variable sampling clock.

10. The piezoelectric actuator driving device of claim 2, wherein the sampling clock generation unit divides the frequency of the predetermined unit clock to generate the variable sampling clock.

11. The piezoelectric actuator driving device of claim 10, wherein the sampling clock generation unit includes:
a unit clock generator generating a unit clock;
a frequency-division-ratio determiner determining a frequency division ratio of the unit clock for the variable sampling clock; and
a frequency divider dividing the frequency of the unit clock according to the frequency division ratio to generate the variable sampling clock.

12. The piezoelectric actuator driving device of claim 2, wherein the digital-to-analog conversion unit includes a binary digital-to-analog converter.

13. A piezoelectric actuator driving device, comprising:
a control unit outputting digital values for generating an output waveform based on a variable sampling clock generated using a frequency of the output waveform; and
a digital-to-analog conversion unit outputting analog values corresponding to the digital values output from the control unit.

14. A piezoelectric actuator driving circuit, comprising:
a sampling clock generation circuit checking a frequency of an output waveform and generating a variable sampling clock considering the frequency of the output waveform; and
a control circuit outputting digital values referring to a predetermined look-up table based on the variable sampling clock.

15. The piezoelectric actuator driving circuit of claim 14, wherein the look-up table includes a plurality of digital values for generating the reference waveform at a predetermined reference sampling clock.

16. The piezoelectric actuator driving circuit of claim 15, wherein the sampling clock generation circuit determines the variable sampling clock by applying a ratio of a frequency of the output waveform to a frequency of the reference waveform in the reference sampling clock.

17. The piezoelectric actuator driving circuit of claim 15, wherein the sampling clock generation circuit includes:
a unit clock generator generating a unit clock;
a frequency-division-ratio determiner determining a frequency division ratio of the unit clock for the variable sampling clock; and
a frequency divider dividing the frequency of the unit clock according to the frequency division ratio to generate the variable sampling clock.

18. The piezoelectric actuator driving circuit of claim 15, wherein the look-up table further includes information on a predetermined reference amplitude, and the control circuit compares an amplitude of an output waveform included in the waveform information with the reference amplitude to calculate an amplitude factor, and applies the calculated amplitude factor to the digital values in the look-up table to output them.

19. A driving signal generating circuit, comprising:
a sampling clock generation circuit checking a frequency of an output waveform and generating a variable sampling clock considering the frequency of the output waveform; and
a digital-to-analog conversion circuit sequentially receiving a plurality of digital values and sequentially outputting analog values corresponding to the plurality of digital values based on the variable sampling clock.

20. The driving signal generating circuit of claim 19, wherein the sampling clock generation circuit includes:
a unit clock generator generating a unit clock;
a frequency-division-ratio determiner determining a frequency division ratio of the unit clock for the variable sampling clock; and
a frequency divider dividing the frequency of the unit clock according to the frequency division ratio to generate the variable sampling clock.

21. The driving signal generating circuit of claim 19, wherein the digital-to-analog conversion circuit includes a binary digital-to-analog converter.

22. A method of driving a piezoelectric actuator, the method comprising:
checking a frequency of an output waveform and generating a variable sampling clock considering the frequency of the output waveform;
outputting at least some of a plurality of digital values included in a predetermined look-up table; and
outputting analog values corresponding to the at least some of the digital values based on the variable sampling clock.

23. The method of claim 22, wherein the generating of the variable sampling clock includes:
calculating a ratio of the frequency of the output waveform to a frequency of a reference waveform of the look-up table; and
determining a frequency of the variable sampling clock by applying the ratio to the reference sampling clock for the reference waveform.

24. The method of claim 23, wherein the generating of the variable sampling clock includes:
determining a frequency division ratio of a predetermined unit clock to the variable sampling clock; and
dividing the frequency of the unit clock based on the frequency division ratio to generate the variable sampling clock.

25. The method of claim 22, wherein the outputting of the at least some of the plurality of digital values includes outputting all of the plurality of digital values included in the look-up table at every period of the output waveform.

26. The method of claim 22, wherein the outputting of the at least some of the plurality of digital values includes comparing an amplitude of the output waveform with a reference amplitude of the look-up table to calculate an amplitude factor, and
reflecting the amplitude factor in the at least some of the plurality of digital values to output them.
